(19) United States
(12) Patent Application Publication
(10) Pub. No.: US 2026/0123261 A1
(43) Pub. Date: Apr. 30, 2026

(54) DISPLAY PANEL AND DISPLAY DEVICE

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CL)

(21) Appl. No.: 19/369,364

(22) Filed: Oct. 27, 2025

(30) Foreign Application Priority Data
Oct. 31, 2024 (CN) 202411552735.5

(51) Int. Cl. H10K 59/80; H10K 59/122; H10K 59/127

(52) U.S. Cl. CPC H10K 59/8794; H10K 59/122; H10K 59/127; H10K 59/80521

(57) ABSTRACT

A display panel and a display device are provided. The display panel may include a driving substrate, a light-emitting support plate, and multiple thermoelectric conversion units. The driving substrate may include a driving circuit layer and multiple driving electrodes. The light-emitting support plate may include: a glass substrate, arranged on the driving substrate and including multiple electrode through holes, where the multiple electrode through holes and the multiple driving electrodes are arranged in one-to-one correspondence; multiple light-emitting units, arranged in an array on and a side of the glass substrate away from the driving substrate, where each of the light-emitting units is electrically connected to a corresponding one of the driving electrodes through a corresponding one of the electrode through holes. Each thermoelectric conversion unit is arranged between adjacent two of the light-emitting units.

### CROSS REFERENCE TO RELATED APPLICATIONS

The present disclosure claims priority of Chinese Patent Application No. 202411552735.5, filed on October 31, 2024, the entire contents of which are hereby incorporated by reference in their entireties.

### TECHNICAL FIELD

The present disclosure relates to the field of display technologies, and in particular to a display panel and a display device.

### BACKGROUND

A single-crystal silicon driving back panel is a driving substrate formed by using a semiconductor component as a driving unit, and the semiconductor component is formed through a complementary metal oxide semiconductor (CMOS) process. Compared with a conventional active-matrix organic light-emitting diode (AMOLED) panel which utilizes an amorphous silicon transistor, a microcrystalline silicon transistor, or a low-temperature polysilicon thin-film transistor as a back panel, the single-crystal silicon driving back panel has a higher support plate mobility. Therefore, a silicon-based organic light emitting diode (OLED) display panel is a type of display panel with the most excellent performance currently applied to a product in an augmented reality (AR)/virtual reality (VR) field.

At present, in a silicon-based OLED display panel, a conventional externally bonded display chip is integrated into a silicon-based driving back panel, and a manufacturing method thereof is that an OLED light-emitting component is fabricated on a silicon-based driving substrate by evaporation. A specific process of the manufacturing method may include: depositing an anode, fabricating a pixel defining layer, and sequentially depositing an organic light-emitting layer and a cathode, such that a smaller-size pixel unit is fabricated, thereby achieving display fineness beyond the retinal-level standard, which may have many advantages such as high resolution, high integration, low power consumption, small volume, light weight, etc.

However, in an actual use process, a light-emitting element layer or a driving substrate is prone to heat, such that a large temperature difference is likely to be generated between the light-emitting element layer and the driving substrate. Too high temperature may affect characteristics of the silicon-based component and light-emitting efficiency of a light-emitting unit.

### SUMMARY OF THE DISCLOSURE

According to a first aspect, some embodiments of the present disclosure provide a display panel. The display panel may include a driving substrate, including a driving circuit layer and a plurality of driving electrodes electrically connected to the driving circuit layer; and a light-emitting support plate, including: a glass substrate, arranged on the driving substrate, and including a plurality of electrode through holes, where the plurality of electrode through holes and the plurality of driving electrodes are arranged in one-to-one correspondence; and a plurality of light-emitting units, arranged in an array and on a side of the glass substrate away from the driving substrate, where each of the light-emitting units is electrically connected to a corresponding one of the driving electrodes through a corresponding one of the electrode through holes; where the display panel further includes a plurality of thermoelectric conversion units, each thermoelectric conversion unit is arranged between adjacent two of the light-emitting units, and a side of each thermoelectric conversion unit is close to the adjacent two of the light-emitting units, and another side of each thermoelectric conversion unit is close to the driving substrate; and each thermoelectric conversion unit is configured to generate a potential difference under an action of a temperature difference between the driving substrate and a corresponding one of the light-emitting units, and each thermoelectric conversion unit is further configured to generate a temperature difference between the side of each thermoelectric conversion unit close to the adjacent two of the light-emitting units and the another side of each thermoelectric conversion unit close to the driving substrate by an action of a driving current thereof.

According to a second aspect, some embodiments of the present disclosure provide a display device. The display device may include the display panel according to the above-mentioned embodiment; and a control circuit board, electrically connected to the display panel, configured to control the display panel to display a corresponding image, configured to control collection of electric energy generated by the thermoelectric conversion unit under the action of the temperature difference, and further configured to control the thermoelectric conversion unit to generate a temperature difference between opposite sides of the thermoelectric conversion unit.

### BRIEF DESCRIPTION OF THE DRAWINGS

In order to more clearly describe the technical solutions in the embodiments of the present disclosure, the following may briefly introduce the drawings required in the description of the embodiments. Obviously, the drawings in the following description are only some embodiments of the present disclosure. For those skilled in the art, other drawings may be obtained based on these drawings without creative work.

FIG. 1 is a structural schematic diagram of a display panel according to some embodiments of the present disclosure.

FIG. 2a is a schematic diagram of a first working principle of a thermoelectric conversion unit according to some embodiments of the present disclosure.

FIG. 2b is a schematic diagram of a second working principle of a thermoelectric conversion unit according to some embodiments of the present disclosure.

FIG. 3 is a structural schematic diagram of an electrode through hole and a thermoelectric through hole according to some embodiments of the present disclosure.

FIG. 4 is a structural schematic diagram of a display panel according to some embodiments of the present disclosure.

FIG. 5 is a structural schematic diagram of the display panel according to some embodiments of the present disclosure.

FIG. 6 is a structural schematic diagram of the display panel according to some embodiments of the present disclosure.

FIG. 7 is a structural schematic diagram of the thermoelectric conversion unit according to some embodiments of the present disclosure.

FIG. 8 is a structural schematic diagram of the thermoelectric conversion unit according to some embodiments of the present disclosure.

FIG. 9 is a structural schematic diagram of a light-emitting support plate according to some embodiments of the present disclosure.

FIG. 10 is a structural schematic diagram of a display device according to some embodiments of the present disclosure.

### DETAILED DESCRIPTION

The technical solutions of the embodiments of the present disclosure may be described in detail below in conjunction with the accompanying drawings.

In the following description, for purposes of illustration rather than limitation, specific details, such as specific system architectures, interfaces, and techniques, are set forth in order to provide a thorough understanding of the present disclosure.

The following may clearly and completely describe the technical solutions in the embodiments of the present disclosure in conjunction with the accompanying drawings in the embodiments of the present disclosure. Obviously, the described embodiments are only part of the embodiments of the present disclosure, not all of them. Based on the embodiments of the present disclosure, all other embodiments acquired by those skilled in the art without creative work shall fall within the scope of protection in the present disclosure.

The terms “first”, “second”, and “third” in the present disclosure are used for descriptive purposes only, and cannot be understood as indicating or implying relative importance or implicitly specifying the quantity of indicated technical features. Thus, features defined as “first”, “second”, and “third” may explicitly or implicitly include at least one of these features. In the description of the present disclosure, “a plurality of/multiple” means at least two, such as two, three, etc., unless otherwise specifically defined. All directional indications (such as up, down, left, right, front, back . . .) in the embodiments of the present disclosure are only used to explain the relative positional relationships, movements, etc., of components in a certain posture (as shown in the figure), and if the specific posture is changed, the directional indications are also changed accordingly. Furthermore, the terms “include”, “have”, and any variations thereof, are intended to cover a non-exclusive inclusion. For example, a process, method, system, product, or device including a series of operations or units is not limited to the listed operations or units, but optionally also may include unlisted operations or units, or optionally may further include other operations or units inherent in the process, method, product, or device.

Reference to “embodiment” in the present disclosure means that, specific features, structures, or characteristics described in conjunction with the embodiments may be included in at least one embodiment of the present disclosure. The presence of the phrase at each location in the specification does not necessarily refer to the same embodiment, nor is it a separate or alternative embodiment that is mutually exclusive with other embodiments. It is understood, both explicitly and implicitly, by those skilled in the art that embodiments described herein may be combined with other embodiments.

The present disclosure may be described in detail below in conjunction with the accompanying drawings and embodiments.

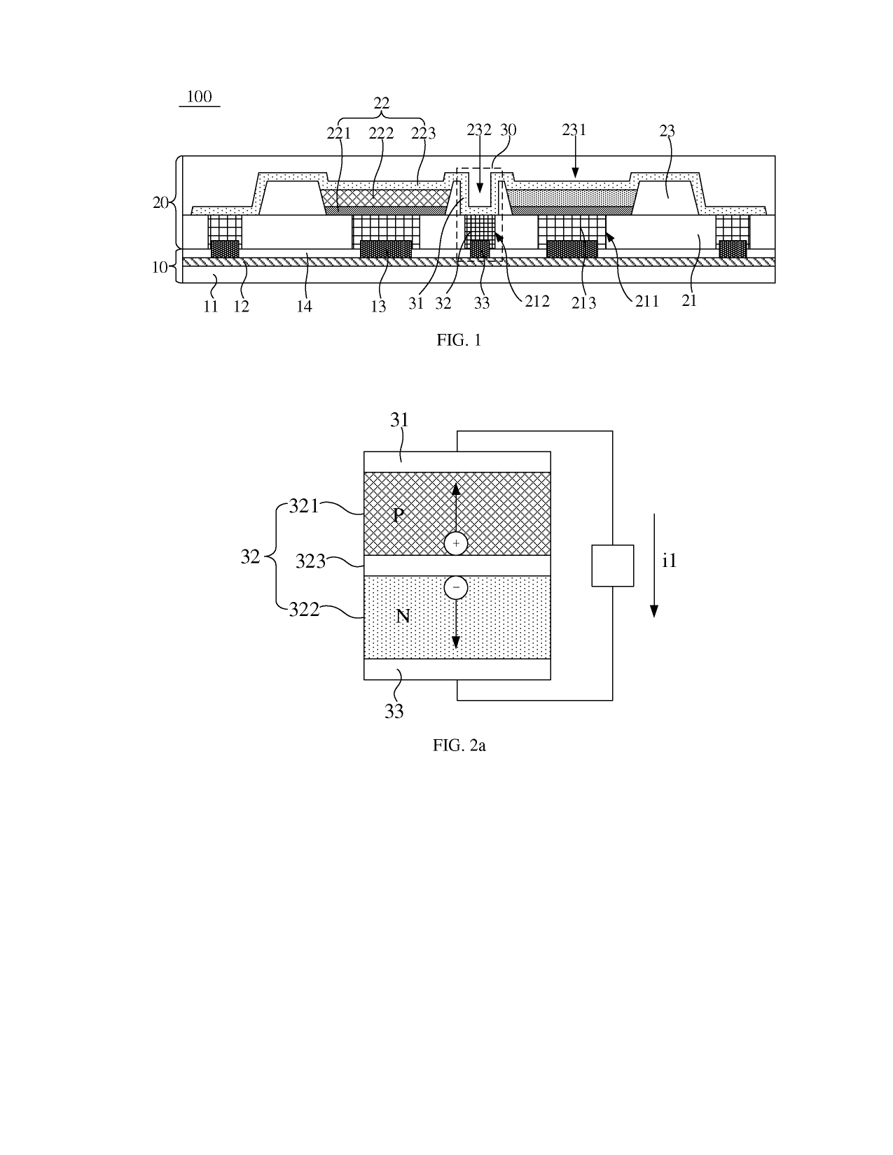

As shown in FIG. 1, FIG. 1 is a structural schematic diagram of a display panel according to some embodiments of the present disclosure. A display panel 100 may be provided by some embodiments of the present disclosure. In the embodiments, the display panel 100 may include a driving substrate 10 and a light-emitting support plate 20. The driving substrate 10 may be aligned with and electrically connected to the light-emitting support plate 20, so as to drive the light-emitting support plate to display an image.

The driving substrate 10 may include a driving circuit layer 12 and multiple driving electrodes 13 electrically connected to the driving circuit layer 12. In some embodiments, the driving circuit layer 12 may include multiple pixel driving circuits (not shown), and each pixel driving circuit may include a semiconductor driving component. In some embodiments, a complementary metal oxide semiconductor (CMOS) component may be served as the semiconductor driving component to form the multiple pixel driving circuits, so as to drive the light-emitting support plate 20 to emit light. The multiple driving electrodes 13 may be electrically connected to the multiple pixel driving circuits in one-to-one correspondence, and the multiple driving electrodes 13 may be electrically connected to power supply signals, such that the multiple driving electrodes 13 may be configured to transmit corresponding driving signals to the light-emitting support plate 20.

In some embodiments, the driving substrate 10 may further include a silicon-based substrate 11 and an insulating protection layer 14. The silicon-based substrate 11 may be configured to carry the driving circuit layer 12, the multiple driving electrodes 13, the insulating protection layer 14, and other film layers. In some embodiments, the silicon-based substrate 11 may be configured as a single-crystal silicon substrate. The insulating protection layer 14 may be disposed at a side of the driving circuit layer 12 away from the silicon-based substrate 11. Multiple openings may be defined on the insulating protection layer 14. The multiple openings and the multiple driving electrodes 13 may be arranged in one-to-one correspondence, such that the multiple driving electrodes 13 may be exposed, i.e., the multiple driving electrodes 13 may be exposed from the insulating protection layer 14. That is, an orthographic projection of a corresponding one of the openings defined on the insulating protection layer 14 on the driving circuit layer 12 may be overlapped with a projection of a corresponding one of the driving electrodes 13 on the driving circuit layer 12, such that the corresponding one of the openings may be opposite to the corresponding one of the driving electrodes 13, so as to expose the corresponding one of the driving electrodes 13.

The light-emitting support plate 20 may include a glass substrate 21 and multiple light-emitting units 22 disposed at a side of the glass substrate 21 away from the driving substrate 10. In some embodiments, the glass substrate 21 may be disposed on the driving substrate 10, and the glass substrate 21 may include multiple electrode through holes 211. The multiple electrode through holes 211 and the multiple driving electrodes 13 may be arranged in one-to-one correspondence, such that each of the light-emitting units 22 may be electrically connected to the corresponding one of the driving electrodes 13 through a corresponding one of the electrode through holes 211. In some embodiments, the corresponding one of the electrode through holes 211 may be filled with a conductive portion 213. In a thickness direction of the glass substrate 21, one of opposite sides of the conductive portion 213 may be electrically connected to the corresponding one of the light-emitting units 22, and the other one of the opposite sides of the conductive portion 213 may be electrically connected to the corresponding one of the driving electrodes 13, so as to implement the connection of the driving signals. The multiple light-emitting units 22 may be arranged in an array and on a side of the glass substrate 21 away from the driving substrate 10. The conductive portion 213 may be covered by an orthographic projection of the each of the light-emitting units 22 on the glass substrate 21, such that each of the light-emitting units 22 may be electrically connected to the corresponding one of conductive portion 213. In some embodiments, the corresponding one of the electrode through holes 211 may be a circular through hole, a rectangular through hole, a polygonal through hole, an oval through hole, or a hole in other shapes. In the thickness direction of the glass substrate 21, the corresponding one of the electrode through holes 211 may be a tapered hole, a straight through hole, or a bilaterally flared hole structure that is narrower in the middle and wider on two sides of the flared hole structure, which may be specifically set according to actual needs.

With the above arrangement, the glass substrate 21 may further be disposed between the driving substrate 10 and the corresponding one of the light-emitting units 22, and the multiple light-emitting units 22 may be formed/arranged on the glass substrate 21. Therefore, during a process of manufacturing the multiple light-emitting units 22, the glass substrate 21 may be configured to protect the driving circuit layer 12 on the driving substrate 10, such that it may be possible to reduce the influence and damage to the driving circuit layer 12 in a case where the multiple light-emitting units 22 are directly manufactured on the driving substrate 10, thereby improving the product yield. The multiple electrode through holes 211 may be defined on the glass substrate 21 and the conductive portion 213 may be disposed in a glass through hole, such that the multiple light-emitting units 22 may be in signal connection with the driving substrate 10 through the conductive portion 213, so as to implement an image display function.

Moreover, by using the glass substrate 21 as a substrate of the light-emitting support plate 20, compared with the silicon-based substrate 11, since the glass substrate 21 has a good insulation performance, it is not necessary to form an oxide insulating layer on a hole wall of the electrode through hole 211 of the glass substrate 21, and special thin wafer holding technology is not required, such that it may be possible to reduce the costs. Moreover, the glass substrate 21 has a lower cost than the silicon substrate, thereby further reducing the costs. At the same time, due to the good insulation performance of the glass substrate 21, an electromagnetic coupling effect may be not easy to occur in a case where signals are transmitted, such that it may be possible to effectively reduce a problem such as signal insertion loss, crosstalk, etc., thereby ensuring the integrity of the signals. In some embodiments, the multiple light-emitting units 22 may be manufactured on the glass substrate 21, such that it may also facilitate realizing a large-size light-emitting support plate 20. In addition, the multiple light-emitting units 22 may be disposed on the glass substrate 21 to form the light-emitting support plate 20, such that the driving substrate 10 and the light-emitting support plate 20 may be separately prepared, and thus it may also be possible to shorten the preparation time, thereby facilitating improving the production cycle.

In the thickness direction of the glass substrate 21, the multiple light-emitting units 22 may include an anode electrode 221, a light-emitting layer 222, and a cathode electrode 223 sequentially stacked along a direction away from the glass substrate 21. The corresponding one of the electrode through holes 211 may be covered by an orthographic projection of the anode electrode 221 on the glass substrate 21, such that the anode electrode 221 may be electrically connected to the corresponding conductive portion 213. Cathode electrodes 223 of each light-emitting unit 22 may be electrically connected to each other. A corresponding one of the cathode electrodes 223 may be electrically connected to the corresponding one of the driving electrodes 13 on the driving substrate 10 through the corresponding one of the electrode through holes 211 disposed at an edge region of the glass substrate 21. Specifically, the corresponding one of the cathode electrodes 223 may be electrically connected to the corresponding one of the driving electrodes 13 through the through the conductive portion 213 disposed in the corresponding one of the electrode through holes 221. In some embodiments, the corresponding one of the light-emitting units 22 may include a first light-emitting unit 22, a second light-emitting unit 22, and a third light-emitting unit 22 with different light-emitting colors. Specifically, the first light-emitting unit 22, the second light-emitting unit 22, and the third light-emitting unit 22 may be a red light-emitting unit 22, a green light-emitting unit 22, and a blue light-emitting unit 22, respectively, so as to realize color display. In some embodiments, a light-emitting color of the corresponding one of the light-emitting units 22 may be determined by a light-emitting color of the light-emitting layer 222. Alternatively, in other embodiments, the corresponding one of the light-emitting units 22 may also be a light-emitting unit having the same color, where the same color may be one of white, red, green, blue, and other color, which may be specifically set according to actual needs. In some embodiments, the corresponding one of the light-emitting units 22 may be a white light-emitting unit, gray-scale display may be realized by controlling the brightness of the corresponding one of the light-emitting units 22, and a color resist layer may be additionally arranged above the corresponding one of the light-emitting units 22 to realize the color display. In some embodiments, the corresponding one of the light-emitting units 22 may be a current-driven light-emitting component, such as an organic light emitting diode (OLED), a light emitting diode (LED), a mini light emitting diode (Mini-LED), a micro light emitting diode (Micro-LED), or a combination thereof. In the embodiments, the corresponding one of the light-emitting units 22 is an OLED as an example for description.

In some embodiments, the light-emitting support plate 20 may further include an encapsulation layer configured to encapsulate the multiple light-emitting units 22 and a color film layer disposed on the encapsulation layer. The color film layer may include a black matrix and multiple color resist layers. The multiple color resist layers and the multiple light-emitting units 22 may be arranged in one-to-one correspondence, a corresponding one of the color resist layers may be aligned with the corresponding one of the light-emitting units 22.

During an actual use process of the above silicon-based OLED display panel 100, since the light-emitting support plate 20 may be disposed at an upper part of the display panel 100, that is, the light-emitting support plate 20 may be disposed at a side of the driving substrate 10 close to a light-emitting side of the display panel 100, the light-emitting support plate 20 may be easy to absorb heat and generate heat in extreme high outdoor temperature. In addition, under a prolonged extreme heavy-load power condition, the driving substrate 10 may be easy to power overload, resulting in severe heat generation. Each of the above situations may cause a large temperature difference between the driving substrate 10 and the light-emitting support plate 20, and too high temperature may affect the characteristics of a silicon-based driving component on the driving substrate 10 and the light-emitting efficiency of each light-emitting unit 22 of the light-emitting support plate 20. Moreover, in extreme low outdoor temperature, the light-emitting efficiency of each light-emitting unit 22 may be easy to decrease due to the influence of the low temperature, resulting in a decrease in the brightness of the display panel 100 and a display abnormality.

To solve the above problems, in the embodiments, the display panel 100 may further include a plurality of thermoelectric conversion units 30. each of the thermoelectric conversion units 30 may be disposed between adjacent two of the light-emitting units 22. A side of each thermoelectric conversion unit 30 may be close to the adjacent two of the light-emitting units 22, and another side of each thermoelectric conversion unit 30 may be close to the driving substrate 10. Each thermoelectric conversion unit 30 may be configured to generate a potential difference under an action of a temperature difference between the driving substrate 10 and the corresponding one of the light-emitting units 22. Each thermoelectric conversion unit 30 may be further configured to generate a temperature difference between the side of each thermoelectric conversion unit 30 close to the adjacent two of the light-emitting units 22 and the another side of each thermoelectric conversion unit 30 close to the driving substrate 10 by an action of a driving current i2 thereof.

In the embodiments, each thermoelectric conversion unit 30 may be disposed between adjacent two of the light-emitting units 22, the side of each thermoelectric conversion unit 30 may be close to the adjacent two of the light-emitting units 22, and the another side of each thermoelectric conversion unit 30 may be close to the driving substrate 10. Therefore, in a case where the temperature difference is generated between the driving substrate 10 and the multiple light-emitting units 22, each thermoelectric conversion unit 30 may be configured to generate the potential difference under the action of the temperature difference, so as to convert heat energy into electrical energy. The converted electrical energy may be stored or be used, thereby utilizing the temperature difference generated between the driving substrate 10 and the multiple light-emitting units 22 At the same time, it may be possible to alleviate/reduce the influence of the temperature difference on the characteristics of the silicon-based device, so as to prevent the light-emitting efficiency of each light-emitting unit 22 from being decreased. At the same time, the driving current i2 may be applied/input to each thermoelectric conversion unit 30, such that each thermoelectric conversion unit 30 may be configured to generate the temperature difference between the side of each thermoelectric conversion unit 30 close to the adjacent two of the light-emitting units 22 and the another side of each thermoelectric conversion unit 30 close to the driving substrate 10 under the action of the driving current i2. In this way, it may be possible to enable the multiple light-emitting units 22/the driving substrate 10 to be heated or to be perform heat dissipation, such that the influence of too high temperature or too low temperature on the service life and the light-emitting efficiency of each light-emitting unit 22 may be reduced, and the influence of too high temperature on the characteristics of the silicon-based driving components on the driving substrate 10 may also be reduced.

In some embodiments, the glass substrate 21 may further include multiple thermoelectric through holes 212 defined therein, and each thermoelectric through hole 212 may be disposed between adjacent two of the electrode through holes 211. Each thermoelectric conversion unit 30 may include a first electrode 31, a thermoelectric conversion layer 32, and a second electrode 33. At least a part of the thermoelectric conversion layer 32 may be disposed in a corresponding one of the thermoelectric through holes 212. The first electrode 31 may be disposed at a side of the thermoelectric conversion layer 32 away from the driving substrate 10. The first electrode 31 may be in contact with the thermoelectric conversion layer 32 to form an electrical connection. The second electrode 33 may be disposed on the driving substrate 10 and in contact with the thermoelectric conversion layer 32 to form an electrical connection. In some embodiments, the material of the thermoelectric conversion layer 32 may be a thermoelectric material, so as to enable each thermoelectric conversion unit 30 to convert heat energy and electrical energy into each other.

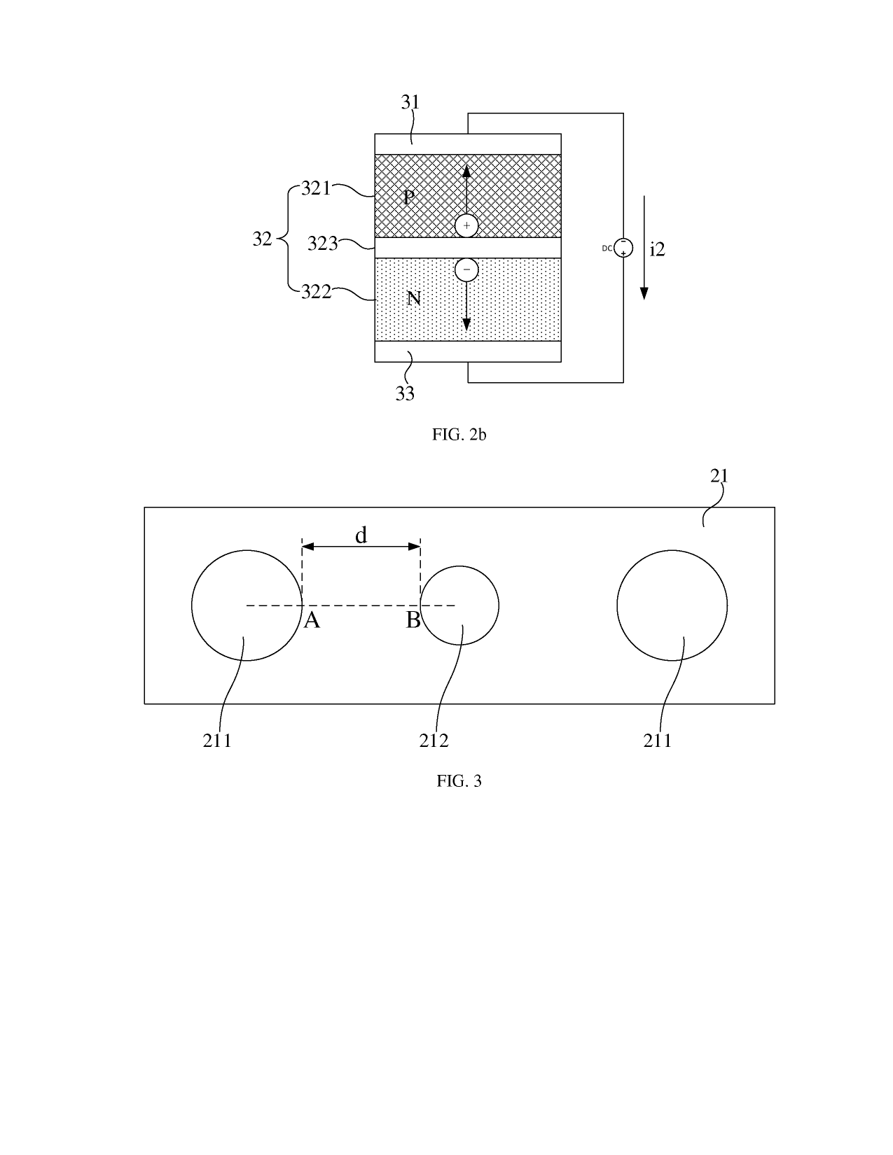

As shown in FIG. 2a, FIG. 2a is a schematic diagram of a first working principle of a thermoelectric conversion unit according to some embodiments of the present disclosure. A working principle that the heat energy may be converted into the electrical energy through each thermoelectric conversion unit 30 may be based on a Seebeck Effect. In the thermoelectric conversion layer 32, the diffusion velocity of electrons may be proportional to the temperature. Therefore, as long as temperature difference between the two sides of the thermoelectric conversion layer 32 may be maintained, the flow of electrons may be maintained, and a potential difference may be formed/generated at two ends of the thermoelectric conversion layer 32.

As shown in FIG. 2a, taking a simplest structure of the thermoelectric conversion layer 32 as an example, the thermoelectric conversion layer 32 may at least include a P-type thermoelectric material layer 321 and an N-type thermoelectric material layer 322. The P-type thermoelectric material layer 321 and the N-type thermoelectric material layer 322 may be connected in series through an intermediate electrode 323. The first electrode 31 may be disposed at one of opposite ends of the thermoelectric conversion layer 32, and the second electrode 33 may be disposed at the other one of the opposite ends of the thermoelectric conversion layer 32. Each of the first electrode 31 and the second electrode 33 may be in contact with and electrically connected to the thermoelectric material layer. Based on the Seebeck Effect, a support plate (i.e., a hole) inside the P-type thermoelectric material layer 321 may migrate along a direction from a side of the first electrode 31 away from the first electrode 31 to the first electrode 31, such that a first potential difference may be formed at two ends of the P-type thermoelectric material layer 321. A support plate (i.e., a free electron) inside the N-type thermoelectric material layer 322 may migrate along a direction from a side of the second electrode 33 away from the second electrode 33 to the second electrode 33, such that a second potential difference may be formed at two ends of the N-type thermoelectric material layer 322. A potential difference between the first electrode 31 and the second electrode 33 may be a sum of the first potential difference and the second potential difference. A direction of the conversion current i1 formed by the potential difference between the first electrode 31 and the second electrode 33 may be flowed from the first electrode 31 to the second electrode 33 outside the thermoelectric conversion layer 32. An energy storage component may be connected between the first electrode 31 and the second electrode 33, so as to store the electrical energy. The larger the temperature difference between temperature at a side of the first electrode 31 and temperature at a side of the second electrode 33, the faster a diffusion rate of the support plate inside the thermoelectric conversion layer 32. The larger the potential difference between the first electrode 31 and the second electrode 33, and the more converted electrical energy. The generated/formed electrical energy may be stored by the energy storage component. Alternatively, the energy storage component may be connected to other electrical components and configured to provide the electrical energy to the other electrical components.

As shown in FIG. 2b, FIG. 2b is a schematic diagram of a second working principle of a thermoelectric conversion unit according to some embodiments of the present disclosure. A working principle that the electrical energy may be converted into the heat energy through each thermoelectric conversion unit 30 may be based on a Peltier Effect. In a case where a thermocouple pair is formed by two different conductor materials and supplied with a direct current, heat absorption phenomena and heat release phenomena may occur at corresponding junctions of the thermocouple pair. In some embodiments, a heat-absorbing end of the thermocouple pair may be a cold end, and a heat-releasing end of the thermocouple pair may be a hot end. The cold end and the hot end may be interchanged by controlling a current direction.

As shown in FIG. 2b, taking a simplest structure of the thermoelectric conversion layer 32 as an example, the thermoelectric conversion layer 32 may at least include a P-type thermoelectric material layer 321 and an N-type thermoelectric material layer 322. The P-type thermoelectric material layer 321 and the N-type thermoelectric material layer 322 may be connected in series through an intermediate electrode 323. The first electrode 31 may be disposed at one of opposite ends of the thermoelectric conversion layer 32, and the second electrode 33 may be disposed at the other one of the opposite ends of the thermoelectric conversion layer 32. Each of the first electrode 31 and the second electrode 33 may be in contact with and electrically connected to the thermoelectric material layers. That is, a thermocouple pair may be formed by the P-type thermoelectric material layer 321 and the N-type thermoelectric material layer 322. Opposite ends of the thermocouple pair may be served as junctions, one of the opposite ends of the thermocouple pair may be close to the corresponding one of the light-emitting units 22, and the other one of the opposite ends of the thermocouple pair may be close to the driving circuit layer 12. In a case where either the corresponding one of the light-emitting units 22 or the driving substrate 10 needs to be heated or to be perform heat dissipation, the driving current i2 may be applied to the first electrode 31 and the second electrode 33. Under the action of the driving current i2, heat may be absorbed at the one of the opposite ends of the thermocouple pair to reduce the temperature, and heat may be released at the other one of the opposite ends of the thermocouple pair to increase the temperature, such that heating or heat dissipation may be needed for a party that needs to be heated or performed heat dissipation. In some embodiments, in a case where heat dissipation is needed for the corresponding one of the light-emitting unit 22, a direction of the driving current i2 may be controlled to enable a side of each thermoelectric conversion unit 30 close to the corresponding one of the light-emitting unit 22 to be served as the cold end. In a case where heat is needed for the corresponding one of the light-emitting unit 22, the direction of the driving current i2 may be controlled to enable a side of each thermoelectric conversion unit 30 close to the corresponding one of the light-emitting unit 22 to be served as the hot end. In a case where the driving substrate 10 needs to be heated or to be perform heat dissipation, the direction of the driving current i2 may also be controlled to enable a side of each thermoelectric conversion unit 30 close to the driving circuit layer 12 to be served as the cold end or the hot end.

In specific implementations, a material of the thermoelectric conversion layer 32 may be a periodic multicycle heterojunction (PMHJ) thermoelectric material. In some embodiments, a PMHJ structure may include two different polymers alternately deposited, and each PMHJ may include two polymer layers and an interface layer with bulk heterojunction characteristics. The PMHJ structure may be prepared in a large area with good uniformity by a solution method for a PMHJ thin film. The thermoelectric conversion layer 32 may be made of the PMHJ thermoelectric material, such that the thermoelectric conversion layer 32 may perform well in thermal conductivity, bending radius, normalized power density, large-area preparation capability, and low processing temperature. Therefore, each thermoelectric conversion unit 30 may have high thermoelectric conversion efficiency, thereby having high heat dissipation efficiency and heating efficiency.

As further shown in FIG. 1, in the embodiments, the light-emitting support plate 20 may further include a pixel defining layer 23 disposed on the glass substrate 21. Multiple pixel openings 231 may be defined on the pixel defining layer 23. The multiple pixel openings 231 and the multiple light-emitting units 22 may be arranged in one-to-one correspondence. An anode electrode 221, a light-emitting layer 222, and a cathode electrode 223 may be sequentially stacked in a corresponding one of the pixel openings 231 along a direction of the glass substrate 21 away from the driving substrate 10, so as to form the corresponding one of the light-emitting units 22. In some embodiments, the pixel defining layer 23 may be configured to separate the anode electrodes 221 and the light-emitting layers 222 of different light-emitting units 22, so as to prevent cross-color interference between different light-emitting units 22.

The pixel defining layer 23 may further include multiple thermoelectric openings 232. Each thermoelectric opening 232 may be disposed between adjacent two of the pixel openings 231. Each thermoelectric through hole 212 may be covered by an orthographic projection of a corresponding one of the thermoelectric openings 232 on the glass substrate 21, that is, each thermoelectric opening 232 may be in communication with the corresponding one of the thermoelectric through holes 212. The first electrode 31 may be disposed in a corresponding one of the thermoelectric openings 232. The first electrode 31 may be in contact with the thermoelectric conversion layer 32 to form an electrical connection.

In some embodiments, the cathode electrode 223 may extend beyond the corresponding one of the pixel openings 231. The cathode electrode 223 may be extended into to a corresponding one of the thermoelectric openings 232 along a surface of the pixel defining layer 23 away from the glass substrate 21. The cathode electrode 223 may be connected to another adjacent cathode electrode 223. The cathode electrode 223 may also be served as the first electrode 31 of each thermoelectric conversion unit 30, such that a structure of the display panel 100 may be simplified without the need for an additional electrode layer.

With the above settings, in a case where a temperature difference is generated between the light-emitting support plate 20 and the driving substrate 10, a potential difference may be generated between the cathode electrode 223 and the second electrode 33 of the driving substrate 10 under the action of the temperature difference, such that the heat energy may be converted into the electrical energy. The generated electrical energy may be stored in the storage component, or the generated electrical energy may be provided to the other electrical components, such that it may be possible to utilize the temperature difference generated between the light-emitting support plate 20 and the driving substrate 10, thereby improving energy utilization, and alleviating/reducing the temperature difference. At the same time, in a case where the light-emitting support plate 20 or the driving substrate 10 needs to be heated or to be perform heat dissipation, the driving current i2 may be applied between the cathode electrode 223 and the second electrode 33, such that a temperature difference may be generated between opposite sides of each thermoelectric conversion unit 30. By controlling the direction of the driving current i2, heat dissipation or heating may be performed for one of the opposite sides of each thermoelectric conversion unit 30. In some embodiments, the cathode electrode 223 may maintain a cathode potential signal. The direction of the driving current i2 applied to each thermoelectric conversion unit 30 may be controlled by controlling a potential of the second electrode 33, such that the cathode signal of the cathode electrode 223 may be unchanged while heat dissipation or heating may be achieved, thereby ensuring that the display panel 100 may normally display the image.

As shown in FIG. 3, FIG. 3 is a structural schematic diagram of an electrode through hole and a thermoelectric through hole according to some embodiments of the present disclosure. In the embodiments, a spacing d between each thermoelectric through hole 212 and a corresponding one of the adjacent two of the electrode through holes 211 may be at least greater than 1 μm. It should be noted that the corresponding one of the electrode through holes 211 here may be referred to an electrode through hole 211 closest to a corresponding one of the thermoelectric through holes 212. The spacing d between each thermoelectric through hole 212 and the corresponding one of the electrode through holes 211 may be defined as follows. On a connecting line between a central axis of each thermoelectric through hole 212 and a central axis of the corresponding one of the electrode through holes 211, an intersection point of the corresponding one of the electrode through holes 211 and the connecting line is a point A, and an intersection point of each thermoelectric through hole 212 and the connecting line is a point B. A distance AB between the point A and the point B is the spacing d between each thermoelectric through hole 212 and the corresponding one of the electrode through holes 211.

In some embodiments, on a premise that the spacing d between each thermoelectric through hole 212 and the corresponding one of the electrode through holes 211 is at least greater than 1 μm, a diameter of the corresponding one of the electrode through holes 211 and a diameter of each thermoelectric through hole 212 may be set according to actual needs. In some embodiments, the diameter of the corresponding one of the electrode through holes 211 and the diameter of each thermoelectric through hole 212 may be determined according to a drilling process. In some embodiments, in a case of limited space, the diameter of the corresponding one of the electrode through holes 211 may be preferentially ensured, and the diameter of each thermoelectric through hole 212 may be appropriately reduced. It should be noted that the diameter of each thermoelectric through hole 212 should also be ensured as much as possible, so as to ensure the thermoelectric conversion efficiency.

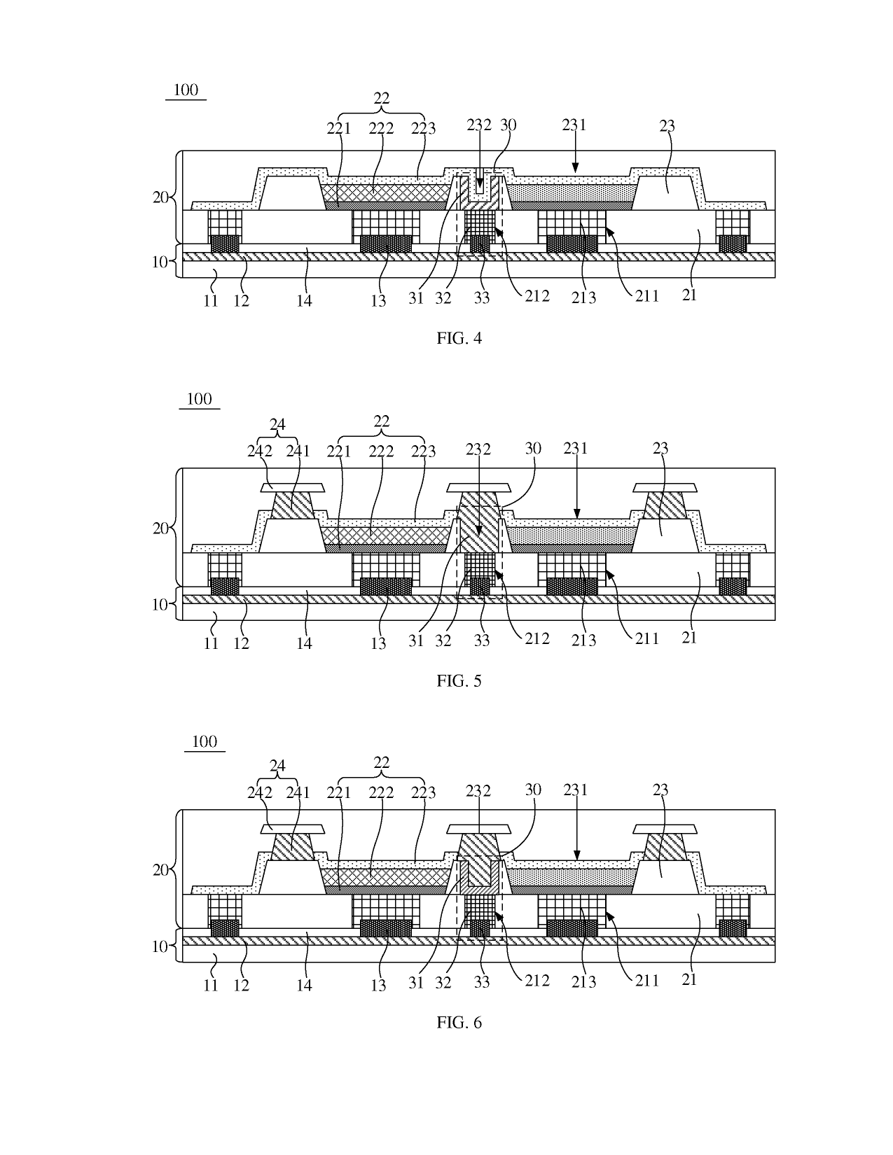

As shown in FIG. 4, FIG. 4 is a structural schematic diagram of a display panel according to some embodiments of the present disclosure. Different from the embodiments as described above, in the embodiments, the first electrode 31 of each thermoelectric conversion unit 30 may be separately arranged. In some embodiments, the first electrode 31 may be disposed in the corresponding one of the thermoelectric openings 232, and disposed at the side of the thermoelectric conversion layer 32 away from the driving substrate 10. The first electrode 31 may be in contact with the thermoelectric conversion layer 32 to form an electrical connection. The cathode electrode 223 may extend beyond the corresponding one of the pixel openings 231. The cathode electrode 223 may be extended into to the corresponding one of the thermoelectric openings 232 along the surface of the pixel defining layer 23 away from the glass substrate 21. The cathode electrode 223 may be electrically connected to the first electrode 31.

In the embodiments, the first electrode 31 may be separately served as an electrode of each thermoelectric conversion unit 30, and the material of the first electrode 31 may be a metal material with high electrical conductivity. Therefore, it may be possible to improve the current collection capability and reduce the voltage division loss.

As shown in FIG. 5, FIG. 5 is a structural schematic diagram of the display panel according to some embodiments of the present disclosure. In the embodiments, the light-emitting support plate 20 may further include a conductive isolation structure 24, and the conductive isolation structure 24 may be configured to separate the light-emitting layer 222 of each light-emitting unit 22, so as to realize a pixel array and reduce pixel crosstalk. In addition, the conductive isolation structure 24 may be further configured to conduct the cathode electrode 223 of each light-emitting unit 22, so as to achieve a network connection between the cathode electrodes 223 of different light-emitting units 22, thereby realizing the uniformity of the entire surface signals of the cathode electrodes 223.

The conductive isolation structure 24 may include a conductive layer 241 and an insulating top 242. The conductive layer 241 may be disposed at a side of the pixel defining layer 23 away from the glass substrate 21. The conductive layer 241 may protrude from the pixel defining layer 23 and arranged around the corresponding one of the pixel openings 231. The insulating top 242 may be disposed on a side surface of the conductive layer 241 away from the pixel defining layer 23. The insulating top 242 may be configured to shield the conductive layer 241, and may extend beyond the conductive layer 241 in a direction parallel to the pixel defining layer 23. The cathode electrode 223 may be extended into the conductive layer 241 and in contact with the conductive layer 241 to form an electrical connection. That is, a part of a top structure of the conductive isolation structure 24 extending beyond the conductive layer 241 may be suspended relative to the conductive layer 241 to form an overhanging structure. During a process of evaporating the light-emitting layer 222 and the cathode electrode 223, an organic light-emitting layer 222 and the cathode electrode 223 may be deposited in a faulted manner at a bottom of the corresponding one of the pixel openings 231 due to the presence of the overhanging structure. After a single light-emitting unit 22 is formed by a single etching, an inorganic encapsulation layer may be configured to encapsulate and protect a monochromatic light-emitting layer 222 and the cathode electrode 223, and an etching protection layer may be formed, and then a preparation of other color organic light-emitting layers 222 and a preparation of other cathode electrodes 223 may be performed one by one. After a patterning of the three-color organic light-emitting layers 222 and a patterning of the cathode electrodes 223 are completed, an organic encapsulation layer and an inorganic encapsulation layer may be configured for an overall encapsulation. In a case where the light-emitting layer 222 and the cathode electrode 223 are evaporated, an edge range of each film layer of the light-emitting layer 222 may be adjusted by adjusting an evaporation angle. The number of conductive isolation structures 24 may be multiple. Adjacent two of the conductive isolation structures 24 may share a same side of a corresponding one of the adjacent two conductive isolation structure 24. That is, sides of the adjacent two conductive isolation structures 24 that are close to each other may share a same side, so as to ensure that a spacing d between the adjacent two of the light-emitting units 22 may be equal, and thus it may be conducive to improving the uniformity of display and increasing a pixel aperture ratio. In some embodiments, the conductive isolation structure 24 may be an annular structure. Specifically, a shape of the conductive isolation structure 24 may match a shape of the corresponding one of the light-emitting units 22, so as to be used for preparing the corresponding one of the light-emitting units 22 with a preset shape.

In a direction perpendicular to the light-emitting support plate 20, a longitudinal section of a sidewall of the conductive layer 241 may be trapezoidal. In addition, in a direction parallel to the light-emitting support plate 20, a cross-sectional area of a sidewall of the conductive layer 241 may gradually decrease along a direction close to the insulating top 242. Therefore, it may be possible to facilitate the contact between the cathode electrode 223 and the conductive layer 241.

In some embodiments, a material of the conductive layer 241 may be a metal material and a conductive oxide material. The metal material may be a metal material with high electrical conductivity such as copper (Cu), aluminum (Al), silver (Ag), gold (Au), or an alloy thereof. The conductive oxide may be a metal oxide material with high electrical conductivity such as indium tin oxide (ITO), indium zinc oxide (IZO), indium gallium zinc oxide (IGZO), etc. In some embodiments, a conductive oxide film may be coated on a surface of a metal film to form a passivation protection layer, so as to protect the metal film.

In some embodiments, a side of the conductive layer 241 close to the thermoelectric conversion layer 32 may be extended into a corresponding one of the thermoelectric openings 232 and in contact with the thermoelectric conversion layer 32, so as to be served as the first electrode 31. The conductive layer 241 may also be served as the first electrode 31 of each thermoelectric conversion unit 30, such that a structure of the display panel 100 may be simplified without the need for an additional electrode layer.

In some embodiments, in a case where the temperature difference between the corresponding one of the light-emitting units 22 and the driving substrate 10 is greater than a first threshold, a potential difference may be generated between the first electrode 31 and the second electrode 33, such that the temperature difference may be converted into the electrical energy through each thermoelectric conversion unit 30. The converted electrical energy may be stored by the energy storage component, and the energy storage component may also be used as a power source to supply power to other components. Alternatively, the converted electrical energy may be directly provided to a related component. Therefore, it may be possible to improve the effective utilization rate of energy. In some embodiments, in a case where the temperature difference between the corresponding one of the light-emitting units 22 and the driving substrate 10 may enable the potential difference between the first electrode 31 and the second electrode 33 of each thermoelectric conversion unit 30 to reach a set value, the temperature difference is the first threshold. The set value of the potential difference may be specifically set according to actual needs, which is not limited herein.

In a case where the temperature of the corresponding one of the light-emitting units 22 is lower than a second threshold, the driving current i2 may be input to the first electrode 31 and the second electrode 33, such that temperature at a side of the thermoelectric conversion layer 32 in contact with the first electrode 31 may be higher than temperature at a side of the thermoelectric conversion layer 32 in contact with the second electrode 33, and thus temperature of the corresponding one of the light-emitting units 22 may be increased. That is, in a case where the temperature of the corresponding one of the light-emitting units 22 is too low, resulting in a decrease in the light-emitting efficiency of each light-emitting unit 22, the driving current i2 may be input to the first electrode 31 and the second electrode 33, such that a side of the thermoelectric conversion layer 32 close to the corresponding one of the light-emitting units 22 may be a hot end, and another opposite side may be a cold end. Therefore, it may be possible to enable the side of the thermoelectric conversion layer 32 close to the corresponding one of the light-emitting units 22 to generate heat, so as to heat the corresponding one of the light-emitting units 22. In some embodiments, the second threshold may be in a range from -40 °C to 0 °C, which may be specifically set according to the decrease in the light-emitting efficiency of the corresponding one of the light-emitting units 22. In some embodiment, temperature at which the light-emitting efficiency of the corresponding one of the light-emitting units 22 is decreased by a% is set as the second threshold, and a% may be in a range from 0% to 40%. In some embodiment, when a% is 20%, the light-emitting efficiency of the corresponding one of the light-emitting units 22 is decreased by 20%, that is, the light-emitting efficiency of the corresponding one of the light-emitting units 22 is 80% of the original light-emitting efficiency, the temperature at this time is the second threshold.

In some embodiment, the second threshold may be set to -25°C. In a case where the temperature of the corresponding one of the light-emitting units 22 close to each thermoelectric conversion unit 30 may be lower than -25°C, the driving current i2 may be input to the first electrode 31 and the second electrode 33, such that it may be possible to enable the side of the thermoelectric conversion layer 32 close to the corresponding one of the light-emitting units 22 to generate heat, so as to heat an adjacent light-emitting unit 22.

In a case where the temperature of the corresponding one of the light-emitting units 22 is higher than a third threshold, the driving current i2 may be input to the first electrode 31 and the second electrode 33, such that the temperature at the side of the thermoelectric conversion layer 32 in contact with the first electrode 31 is reduced, and thus temperature of the corresponding one of the light-emitting units 22 may be decreased. That is, in a case where the temperature of the corresponding one of the light-emitting units 22 is too high, resulting in a decrease in the light-emitting efficiency of the corresponding light-emitting units 22, the driving current i2 may be input to the first electrode 31 and the second electrode 33, such that the side of the thermoelectric conversion layer 32 close to the corresponding one of the light-emitting units 22 may be a cold end, and another opposite side may be a hot end. Therefore, it may be possible to enable the side of the thermoelectric conversion layer 32 close to the corresponding one of the light-emitting units 22 to absorb heat, so as to dissipate heat and cool down the corresponding one of the light-emitting units 22. In some embodiments, the third threshold may be set according to a heating condition of the corresponding one of the light-emitting units 22, which is not specifically limited herein.

Similarly, in a case where temperature of a portion of the driving circuit layer 12 close to a side where each thermoelectric conversion unit 30 is in contact with the second electrode 33 is higher than a fourth threshold, the driving current i2 may be input to the first electrode 31 and the second electrode 33, such that the temperature at the side of the thermoelectric conversion layer 32 in contact with the second electrode 33 is reduced, and thus temperature of the corresponding one of the light-emitting units 22 may be decreased. That is, in a case where the temperature of the driving circuit layer 12 is too high, the driving current i2 may be input to the first electrode 31 and the second electrode 33, such that it may be possible to enable the side of the thermoelectric conversion layer 32 close to the corresponding one of the light-emitting units 22 to absorb heat, so as to dissipate heat and cool down the corresponding one of the light-emitting units 22. In some embodiments, the fourth threshold may be set according to the characteristics of the driving component of the driving circuit layer 12, which is not specifically limited herein.

As shown in FIG. 6, FIG. 6 is a structural schematic diagram of the display panel according to some embodiments of the present disclosure. Different from the embodiments as described above, such as the embodiments in FIG. 5, in the embodiments, the first electrode 31 of each thermoelectric conversion unit 30 may be separately arranged. In some embodiments, the first electrode 31 may be disposed in the corresponding one of the thermoelectric openings 232, and disposed at the side of the thermoelectric conversion layer 32 away from the driving substrate 10. The first electrode 31 may be in contact with the thermoelectric conversion layer 32 to form an electrical connection. The side of the conductive layer 241 close to the thermoelectric conversion layer 32 may be extended into the corresponding one of the thermoelectric openings 232and in contact with the first electrode 31 to form an electrical connection.

In the embodiments, the first electrode 31 may be separately served as an electrode of each thermoelectric conversion unit 30, and the material of the first electrode 31 may be a metal material with high electrical conductivity. Therefore, it may be possible to improve the current collection capability and reduce the voltage division loss.

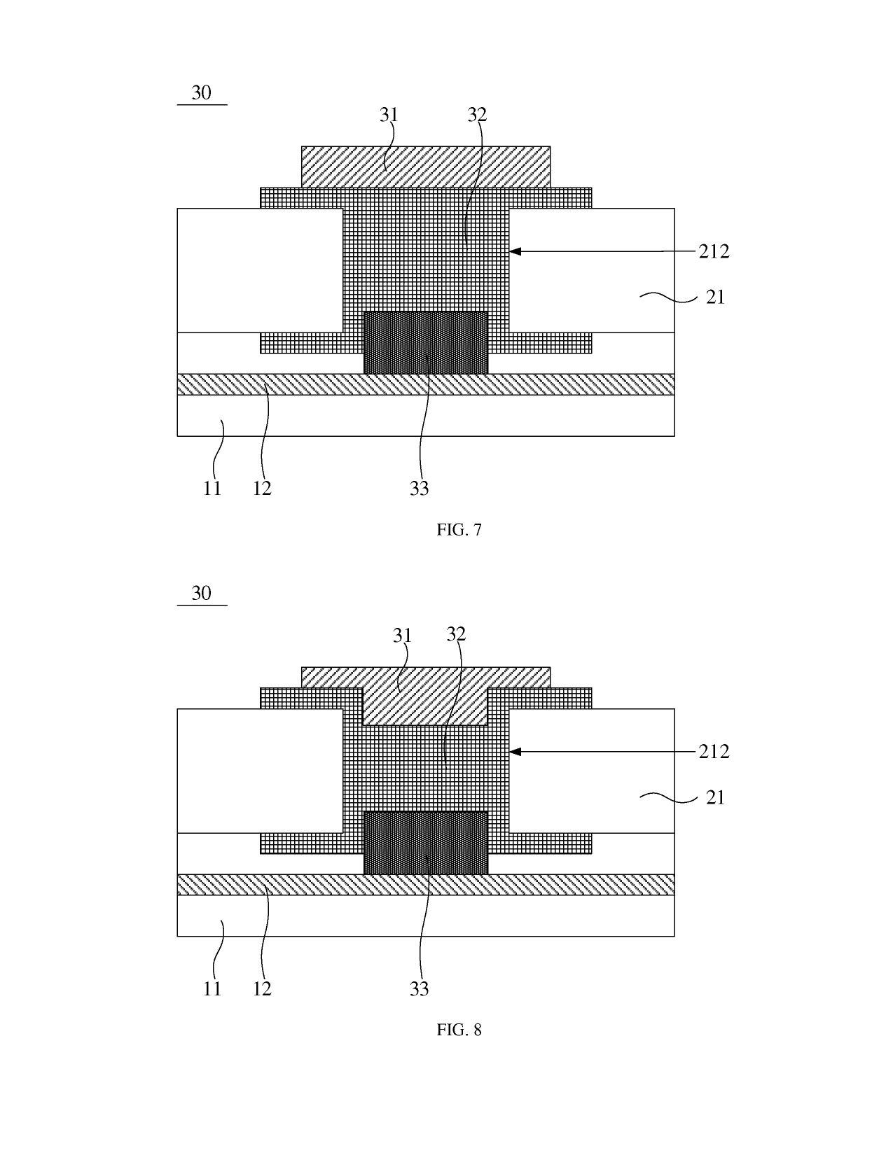

As shown in FIG. 7, FIG. 7 is a structural schematic diagram of the thermoelectric conversion unit according to some embodiments of the present disclosure. The thermoelectric conversion layer 32 may be filled in the corresponding one of the thermoelectric through holes 212. The thermoelectric conversion layer 32 may extend beyond the corresponding one of the thermoelectric through holes 212 in a radial direction of the corresponding one of the thermoelectric through holes 212. The second electrode 33 may be at least partially extended into the corresponding one of the thermoelectric through holes 212 at a side of the second electrode 33 close to the thermoelectric conversion layer 32. The second electrode 33 may be embedded in the thermoelectric conversion layer 32. The first electrode 31 may be disposed on a surface of the thermoelectric conversion layer 32 away from the driving substrate 10and in contact with the thermoelectric conversion layer 32.

In the embodiments, the thermoelectric conversion layer 32 may be filled in the entire corresponding one of the thermoelectric through holes 212, and in the radial direction of the corresponding one of the thermoelectric through holes 212, the thermoelectric conversion layer 32 may extend beyond the corresponding one of the thermoelectric through holes 212 along two side surfaces of the glass substrate 21, such that an extension area of each of two sides of the thermoelectric conversion layer 32 may be increased. Therefore, it may be possible to improve a heat dissipation area of the hot end of the thermoelectric conversion layer 32 and a heat absorption area of the cold end of the thermoelectric conversion layer 32. That is, it may be possible to increase a heating area and a heat dissipation area of the thermoelectric conversion layer 32, so as to improve the energy conversion efficiency.

In the embodiments, the thermoelectric conversion layer 32 may be extended as much as possible without affecting the pixel aperture ratio, so as to further improve the energy conversion efficiency. In some embodiments, the second electrode 33 may be at least partially extended into the corresponding one of the thermoelectric through holes 212 at the side of the second electrode 33 close to the thermoelectric conversion layer 32, and the second electrode 33 may be embedded in the thermoelectric conversion layer 32, such that a contact area between the second electrode 33 and the thermoelectric conversion layer 32 may be increased. Therefore, it may be possible to improve the bonding stability between the second electrode 33 and the thermoelectric conversion layer 32, such that the bonding stability between the light-emitting support plate 20 and the driving substrate 10 may be improved.

As shown in FIG. 8, FIG. 8 is a structural schematic diagram of the thermoelectric conversion unit according to some embodiments of the present disclosure. Different from the embodiments as described above, such as the embodiments in FIG. 7, in the embodiments, the first electrode 31 may be at least partially extended into the corresponding one of the thermoelectric through holes 212 at the side of the first electrode 31 close to the thermoelectric conversion layer 32, and the first electrode 31 may be embedded in the thermoelectric conversion layer 32. That is, each of the first electrode 31 and the second electrode 33 may be extended into the corresponding one of the thermoelectric through holes 212 and embedded in the thermoelectric conversion layer 32.

Through the above arrangement, a contact area between the first electrode 31 and the thermoelectric conversion layer 32 may be improved, such that it may be possible to improve the bonding stability between the first electrode 31 and the thermoelectric conversion layer 32. In addition, it may be possible to further improve a structural stability of each thermoelectric conversion unit 30, and the bonding stability between the light-emitting support plate 20 and the driving substrate 10 may be improved.

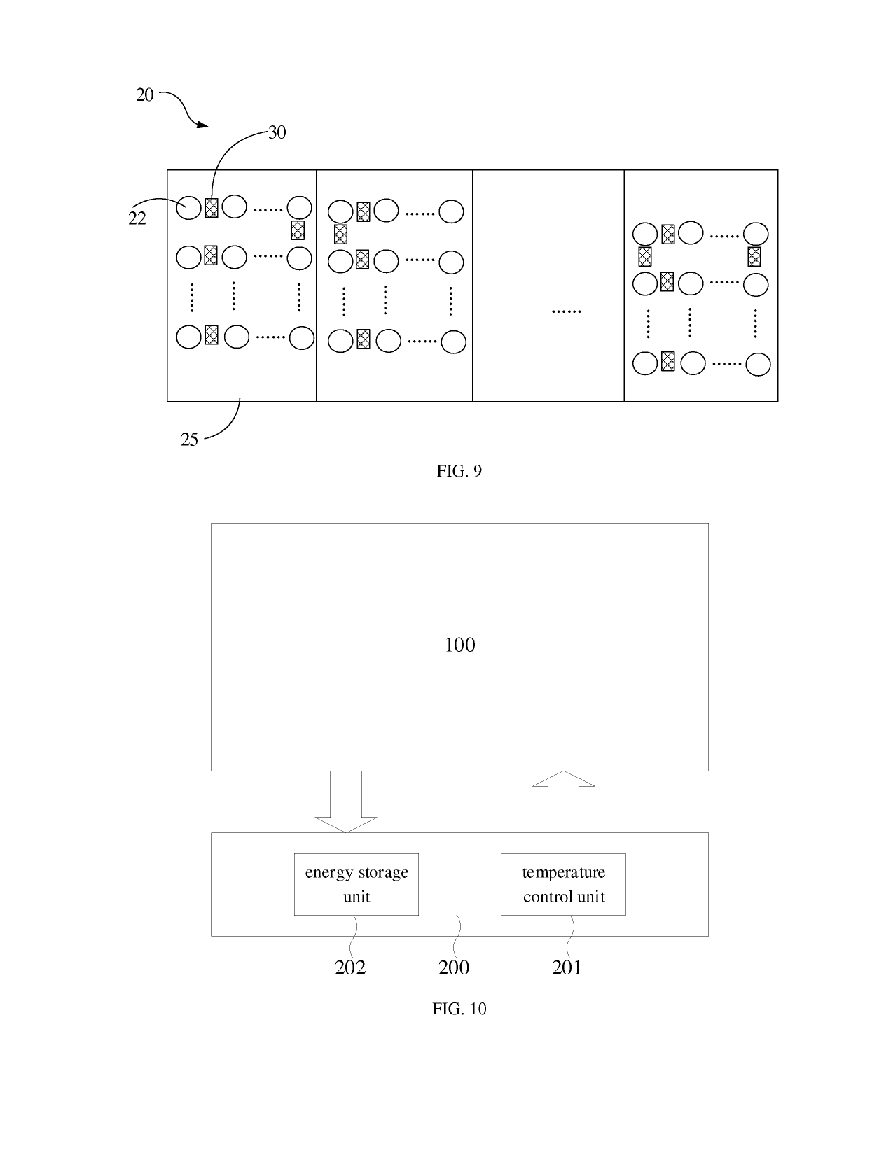

As shown in FIG. 9, FIG. 9 is a structural schematic diagram of a light-emitting support plate according to some embodiments of the present disclosure. In the above embodiments, the light-emitting support plate 20 may be divided into multiple thermoelectric conversion regions 25 spliced with each other. Each thermoelectric conversion region 25 may be arranged with at least two light-emitting units 22 and at least one thermoelectric conversion unit 30. The at least one thermoelectric conversion unit 30 may be uniformly distributed in each thermoelectric conversion region 25.

It may be understood that it is not necessary to define a heating opening in the pixel defining layer 23 disposed below each conductive layer 241 and arrange each thermoelectric conversion unit 30 in the heating opening. The light-emitting support plate 20 may be divided into the multiple thermoelectric conversion regions. Each thermoelectric conversion region 25 may be arranged with m rows and n columns of light-emitting units 22. That is, each thermoelectric conversion region 25 may be arranged with m×n light-emitting units 22, where each of m and n may be a positive integer, and m×n is a positive integer greater than or equal to 2. Each thermoelectric conversion region 25 may be arranged with at least one thermoelectric conversion unit 30, so as to heat the multiple light-emitting units 22 in the thermoelectric conversion region. In some embodiments, each thermoelectric conversion region 25 may be arranged with 2×2 light-emitting units 22 (i.e., four light-emitting units 22) and one thermoelectric conversion unit 30. The one thermoelectric conversion unit 30 may be disposed at a central position of the thermoelectric conversion region, and a distance between each thermoelectric conversion unit 30 and a center point of each of four light-emitting units 22 may be equal, such that the uniformity of heating effect of each thermoelectric conversion unit 30 on each of the four light-emitting units 22 may be improved. In another embodiment, each thermoelectric conversion region 25 may be arranged with m×n light-emitting units 22, where each of m and n may be greater than or equal to 3. Each thermoelectric conversion region 25 may be arranged with several (at least two) thermoelectric conversion units 30, and the several thermoelectric conversion units 30 may be uniformly distributed in each thermoelectric conversion region 25, so as to ensure the balance and conversion efficiency of thermoelectric conversion.

As shown in FIG. 10, FIG. 10 is a structural schematic diagram of a display device according to some embodiments of the present disclosure. In the embodiments, a display device may be provided by some embodiments of the present disclosure. The display device may be applied in a display field such as tablets, mobile phones, vehicles, VR glasses, lighting apparatuses, etc.

The display device may include a display panel 100 and a control circuit board 200. The control circuit board 200 may be electrically connected to the display panel 100. The control circuit board 200 may be configured to provide various driving signals, various power signals, and other driving signals required by the display panel 100 to the display panel 100, so as to control the display panel 100, so as to display a corresponding image.

In some embodiments, a specific structure and a function of the display panel 100 may be the same as or similar to those of the display panel 100 described in the above-mentioned embodiments, which may achieve the same technical effects. For details, reference may be made to the above detailed description. The control circuit board 200 may be further configured to control the collection of the electrical energy generated by each thermoelectric conversion unit 30 under the action of a temperature difference. The control circuit board 200 may be further configured to control each thermoelectric conversion unit 30 to generate a temperature difference between opposite sides of each thermoelectric conversion unit 30.

In some embodiments, the control circuit board 200 may further include a temperature control unit 201 and an energy storage unit 202. The temperature control unit 201 may be electrically connected to each thermoelectric conversion unit 30. The temperature control unit 201 may be configured to control a temperature difference between a side of each thermoelectric conversion unit 30 close to the corresponding one of the light-emitting units 22 and a side of each thermoelectric conversion unit 30 close to the driving substrate 10. The energy storage unit 202 may be electrically connected to the temperature control unit 201 and each thermoelectric conversion unit 30. The temperature control unit 201 may be further configured to control the energy storage unit 202 to store the electrical energy generated by each thermoelectric conversion unit 30.

By arranging the control circuit board 200, the display device may be configured to control the collection of the electrical energy generated by each thermoelectric conversion unit 30 under the action of a temperature difference and control each thermoelectric conversion unit 30 to generate the temperature difference between the opposite sides of each thermoelectric conversion unit 30, such that real-time and local control of heating or performing heat dissipation may be realized. Therefore, directional collection of energy storage or temperature compensation may be achieved, such that the light-emitting efficiency of the display panel 100 may be effectively improved.

Different from the related art, the technical effects of some embodiments of the present disclosure may be as follows. The display panel may include a driving substrate and a light-emitting support plate. The light-emitting support plate may include the glass substrate and the multiple light-emitting units arranged on the glass substrate, and the glass substrate may be arranged on the driving substrate and disposed between the multiple light-emitting units and the driving substrate. Each light-emitting unit may be fabricated on the glass substrate, and the glass substrate may protect a driving circuit layer on the driving substrate, such that it may be possible to reduce the influence and damage to the driving circuit layer in a case where the multiple light-emitting units are directly manufactured on the driving substrate, thereby improving the product yield. Multiple electrode through hole may be defined on the glass substrate, each of the light-emitting units may be electrically connected to a corresponding one of the driving electrodes through a corresponding one of the electrode through holes, so as to display a corresponding image. In some embodiments, each thermoelectric conversion unit may be arranged between adjacent two of the light-emitting units, a side of each thermoelectric conversion unit is close to the adjacent two of the light-emitting units, and another side of each thermoelectric conversion unit is close to the driving substrate. Therefore, each thermoelectric conversion unit may be configured to generate a potential difference under an action of a temperature difference between the driving substrate and a corresponding one of the light-emitting units, so as to convert heat energy into electrical energy, and the converted electrical energy may be stored or utilized. In this way, it may be possible to utilize the temperature difference generated between the driving substrate and each light-emitting unit, and at the same time, it may alleviate/reduce the influence of the temperature difference on the characteristics of a silicon-based component and the reduction of the light-emitting efficiency of each light-emitting unit. In addition, a driving current may be input into each thermoelectric conversion unit, such that each thermoelectric conversion unit may be further configured to generate a temperature difference between the side of each thermoelectric conversion unit close to the adjacent two of the light-emitting units and the another side of each thermoelectric conversion unit close to the driving substrate by an action of a driving current thereof. Therefore, it may be possible to dissipate heat or heat each light-emitting unit or the driving substrate, so as to reduce the influence of too high temperature or too low temperature on the service life and light-emitting efficiency of each light-emitting unit, and the influence of too high temperature on the characteristics of a silicon-based driving component on the driving substrate may also be reduced.

The above shows only embodiments of the present disclosure and does not limit the scope of the present disclosure. Any equivalent structure or equivalent process transformation performed based on the specification and accompanying drawings of the present disclosure, directly or indirectly applied in other related fields, shall be equivalently covered by the present disclosure.

1. A display panel, comprising:
a driving substrate, comprising a driving circuit layer and a plurality of driving electrodes electrically connected to the driving circuit layer; and
a light-emitting support plate, comprising:
a glass substrate, arranged on the driving substrate, and comprising a plurality of electrode through holes, wherein the plurality of electrode through holes and the plurality of driving electrodes are arranged in one-to-one correspondence; and
a plurality of light-emitting units, arranged in an array and on a side of the glass substrate away from the driving substrate, wherein each of the light-emitting units is electrically connected to a corresponding one of the driving electrodes through a corresponding one of the electrode through holes;
wherein the display panel further comprises a plurality of thermoelectric conversion units, each thermoelectric conversion unit is arranged between adjacent two of the light-emitting units, a side of each thermoelectric conversion unit is close to the adjacent two of the light-emitting units, and another side of each thermoelectric conversion unit is close to the driving substrate; and
each thermoelectric conversion unit is configured to generate a potential difference under an action of a temperature difference between the driving substrate and a corresponding one of the light-emitting units, and each thermoelectric conversion unit is further configured to generate a temperature difference between the side of each thermoelectric conversion unit close to the adjacent two of the light-emitting units and the another side of each thermoelectric conversion unit close to the driving substrate by an action of a driving current thereof.

2. The display panel according to claim 1, wherein the glass substrate further comprises a plurality of thermoelectric through holes defined therein, and each thermoelectric through hole is disposed between adjacent two of the electrode through holes;
each thermoelectric conversion unit comprises a first electrode, a thermoelectric conversion layer, and a second electrode, at least a part of the thermoelectric conversion layer is disposed in a corresponding of the thermoelectric through holes, the first electrode is disposed at a side of the thermoelectric conversion layer away from the driving substrate, and the first electrode is in contact with the thermoelectric conversion layer to form an electrical connection; and
the second electrode is arranged on the driving substrate and in contact with the thermoelectric conversion layer to form an electrical connection.

3. The display panel according to claim 2, wherein the light-emitting support plate further comprises a pixel defining layer arranged on the glass substrate, a plurality of pixel openings are defined in the pixel defining layer, and the plurality of pixel openings and the light-emitting units are arranged in one-to-one correspondence;
an anode electrode, a light-emitting layer, and a cathode electrode are sequentially stacked in a corresponding one of the pixel openings along a direction of the glass substrate away from the driving substrate, to form the corresponding one of the light-emitting units;
the pixel defining layer further comprises a plurality of thermoelectric openings, and each thermoelectric opening is disposed between adjacent two of the pixel openings, and each thermoelectric through hole is covered by an orthographic projection of a corresponding one of the thermoelectric openings on the glass substrate; and
the first electrode is disposed in a corresponding one of the thermoelectric openings and in contact with the thermoelectric conversion layer.

4. The display panel according to claim 3, wherein the cathode electrode extends beyond the corresponding one of the pixel openings, the cathode electrode is extended into a corresponding one of the thermoelectric openings along a side surface of the pixel defining layer away from the glass substrate, and the cathode electrode is connected to another adjacent cathode electrode; and
the cathode electrode further serves as the first electrode and in contact with the thermoelectric conversion layer to form an electrical connection, or the cathode electrode is in contact with the first electrode to form an electrical connection.

5. The display panel according to claim 3, wherein the light-emitting support plate further comprises a conductive isolation structure, and the conductive isolation structure comprises a conductive layer and an insulating top;
the conductive layer is disposed at a side of the pixel defining layer away from the glass substrate and arranged around the corresponding one of the pixel openings, and an orthographic projection of a corresponding one of the thermoelectric openings on the glass substrate is covered by an orthographic projection of the conductive layer on the glass substrate;
the insulating top is arranged on a side surface of the conductive layer away from the pixel defining layer, is configured to shield the conductive layer, and extends beyond the conductive layer in a direction parallel to the pixel defining layer;
the cathode electrode is extended into the conductive layer and in contact with the conductive layer to form an electrical connection; and
a side of the conductive layer close to the thermoelectric conversion layer is extended into a corresponding one of the thermoelectric openings and in contact with the thermoelectric conversion layer, and the conductive layer is served as the first electrode; or a side of the conductive layer close to the thermoelectric conversion layer is extended into a corresponding one of the thermoelectric openings and in contact with the first electrode to form an electrical connection.

6. The display panel according to claim 4, wherein the thermoelectric conversion layer is filled in a corresponding one of the thermoelectric openings and extends beyond the corresponding one of the thermoelectric openings in a radial direction of the corresponding one of the thermoelectric openings;
the second electrode is at least partially extended into a corresponding one of the thermoelectric openings at a side of the second electrode close to the thermoelectric conversion layer, and the second electrode is embedded in the thermoelectric conversion layer;
the first electrode is arranged on a surface of the thermoelectric conversion layer away from the driving substrate and in contact with the thermoelectric conversion layer; or the first electrode is at least partially extended into the thermoelectric through hole at a side of the first electrode close to the thermoelectric conversion layer and embedded in the thermoelectric conversion layer.

7. The display panel according to claim 1, wherein the light-emitting support plate is divided into a plurality of thermoelectric conversion regions spliced with each other, each thermoelectric conversion region is arranged with at least two light-emitting units and at least one thermoelectric conversion unit, and the at least one thermoelectric conversion unit is uniformly distributed on each thermoelectric conversion region.

8. The display panel according to claim 2, wherein a material of the thermoelectric conversion layer is a periodic multicycle heterojunction thermoelectric material; and
a spacing between each thermoelectric through hole and a corresponding one of the adjacent two of electrode through holes is greater than 1 µm.

9. The display panel according to claim 2, wherein in a case where the temperature difference between the corresponding one of the light-emitting units and the driving substrate is greater than a first threshold, the potential difference is generated between the first electrode and the second electrode; and
in a case where temperature of the corresponding one of the light-emitting units is less than a second threshold, the driving current is input to the first electrode and the second electrode, such that temperature at a side of the thermoelectric conversion layer in contact with the first electrode is higher than that at a side of the thermoelectric conversion layer in contact with the second electrode, and temperature of the corresponding one of the light-emitting units is increased.

10. The display panel according to claim 3, wherein the corresponding one of the electrode through holes is filled with a conductive portion;
in a thickness direction of the glass substrate, one of opposite sides of the conductive portion is electrically connected to the corresponding one of the light-emitting units, and the other one of the opposite sides of the conductive portion is electrically connected to the corresponding one of the driving electrodes; and
the conductive portion is covered by an orthographic projection of the corresponding one of the light-emitting units on the glass substrate, and the corresponding one of the light-emitting units is electrically connected to the conductive portion.

11. The display panel according to claim 10, wherein a corresponding one of the electrode through holes is covered by an orthographic projection of the anode electrode on the glass substrate, and the anode electrode is electrically connected to a corresponding conductive portion.

12. The display panel according to claim 10, wherein cathode electrodes of each light-emitting unit are electrically connected to each other, a corresponding one of the cathode electrodes is electrically connected to a corresponding one of the driving electrodes through the through the conductive portion disposed in a corresponding one of the electrode through holes.

13. The display panel according to claim 3, wherein the thermoelectric conversion layer at least comprises a P-type thermoelectric material layer and an N-type thermoelectric material layer, and the P-type thermoelectric material layer and the N-type thermoelectric material layer are connected in series through an intermediate electrode; and
the first electrode is disposed at one of opposite ends of the thermoelectric conversion layer, and the second electrode is disposed at the other one of the opposite ends of the thermoelectric conversion layer, and each of the first electrode and the second electrode is in contact with and electrically connected to the thermoelectric material layer.

14. The display panel according to claim 13, wherein a support plate inside the P-type thermoelectric material layer migrate along a direction from a side of the first electrode away from the first electrode to the first electrode, such that a first potential difference is formed at two ends of the P-type thermoelectric material layer;
a support plate inside the N-type thermoelectric material layer migrate along a direction from a side of the second electrode away from the second electrode to the second electrode, such that a second potential difference is formed at two ends of the N-type thermoelectric material layer; and
a potential difference between the first electrode and the second electrode is a sum of the first potential difference and the second potential difference.

15. The display panel according to claim 3, wherein the first electrode is disposed in the corresponding one of the thermoelectric openings, and disposed at a side of the thermoelectric conversion layer away from the driving substrate, and the first electrode is in contact with the thermoelectric conversion layer to form an electrical connection; and
the cathode electrode extends beyond the corresponding one of the pixel openings, the cathode electrode is extended into to the corresponding one of the thermoelectric openings along a surface of the pixel defining layer away from the glass substrate, and the cathode electrode is electrically connected to the first electrode.

16. The display panel according to claim 5, wherein the number of conductive isolation structures is multiple, sides of adjacent two of multiple conductive isolation structures that are close to each other share a same side, and a spacing d between the adjacent two of the light-emitting units is equal.

17. The display panel according to claim 5, wherein in a direction perpendicular to the light-emitting support plate, a longitudinal section of a sidewall of the conductive layer is trapezoidal; and
in a direction parallel to the light-emitting support plate, a cross-sectional area of a sidewall of the conductive layer gradually decreases along a direction close to the insulating top.

18. The display panel according to claim 2, wherein in a case where the temperature of the corresponding light-emitting unit is higher than a third threshold, the driving current is input to the first electrode and the second electrode, such that the temperature at a side of the thermoelectric conversion layer in contact with the first electrode is reduced, and temperature of the corresponding one of the light-emitting units is decreased; and/or
in a case where temperature of a portion of the driving circuit layer close to a side where each thermoelectric conversion unit is in contact with the second electrode is higher than a fourth threshold, the driving current is input to the first electrode and the second electrode, such that the temperature at a side of the thermoelectric conversion layer in contact with the second electrode is reduced, and temperature of the corresponding one of the light-emitting units is decreased.

19. A display device, comprising:
a display panel; and
a control circuit board, electrically connected to the display panel, configured to control the display panel to display a corresponding image, configured to control collection of electric energy generated by the thermoelectric conversion unit under the action of the temperature difference, and further configured to control the thermoelectric conversion unit to generate a temperature difference between opposite sides of the thermoelectric conversion unit;
wherein the display panel comprises:
a driving substrate, comprising a driving circuit layer and a plurality of driving electrodes electrically connected to the driving circuit layer; and
a light-emitting support plate, comprising:
a glass substrate, arranged on the driving substrate, and comprising a plurality of electrode through holes, wherein the plurality of electrode through holes and the plurality of driving electrodes are arranged in one-to-one correspondence; and
a plurality of light-emitting units, arranged in an array and on a side of the glass substrate away from the driving substrate, wherein each of the light-emitting units is electrically connected to a corresponding one of the driving electrodes through a corresponding one of the electrode through holes;
wherein the display panel further comprises a plurality of thermoelectric conversion units, each thermoelectric conversion unit is arranged between adjacent two of the light-emitting units, a side of each thermoelectric conversion unit is close to the adjacent two of the light-emitting units, and another side of each thermoelectric conversion unit is close to the driving substrate; and
each thermoelectric conversion unit is configured to generate a potential difference under an action of a temperature difference between the driving substrate and a corresponding one of the light-emitting units, and each thermoelectric conversion unit is further configured to generate a temperature difference between the side of each thermoelectric conversion unit close to the adjacent two of the light-emitting units and the another side of each thermoelectric conversion unit close to the driving substrate by an action of a driving current thereof.

20. The display device according to claim 19, wherein the control circuit board comprises:
a temperature control unit, electrically connected to each thermoelectric conversion unit, wherein the temperature control unit is configured to control a temperature difference between a side of each thermoelectric conversion unit close to a corresponding one of the light-emitting units and a side of the thermoelectric conversion unit close to the driving substrate; and
an energy storage unit, electrically connected to the temperature control unit and each thermoelectric conversion unit, wherein the temperature control unit is further configured to control the energy storage unit to store the electrical energy generated by the thermoelectric conversion unit.
